(19) United States
(12) Patent Application Publication
(10) Pub. No.: US 2014/0159793 A1
(43) Pub. Date: Jun. 12, 2014

(54) SYSTEM CLOCK MATCHING

(71) Applicant: Robert Bosch GmbH, Stuttgart (DE)

(72) Inventors: Georg Schulze-Icking-Konert, Buehlertal (DE); Michael Forscht, Appenweier (DE)

(21) Appl. No.: 14/098,647

(22) Filed: Dec. 6, 2013

(30) Foreign Application Priority Data
Dec. 6, 2012 (DE) 10 2012 222 428.9

(51) Int. Cl. H03K 5/00

(52) U.S. Cl. CPC H03K 5/00006
USPC 327/299

(57) ABSTRACT

A method for a control device comprising a processing device, an I/O module and a clock generator for providing a system clock, wherein the processing device and the I/O module are designed to operate with the system clock of the clock generator, comprises the steps of determining that capacity utilization of the processing device is exceeding a predetermined threshold, of determining that the I/O module is in a state in which a change in the system clock is uncritical, and of changing the system clock in order to match the performance capacity of the processing device to the capacity utilization.

### BACKGROUND OF THE INVENTION

The invention relates to system clock matching. In particular, the invention relates to matching of a system clock in a control device comprising a processing device and at least one I/O module.

A large number of small electrical devices include a processing device which is implemented as a programmable minicomputer and one or more I/O modules. A heat output of the processing device in this case increases with its system clock. In order to save current, therefore, it is conventional in particular in the case of battery-operated or rechargeable battery-operated devices to match the system clock depending on the capacity utilization of the processing device. Modern microprocessors have special commands with which one of often several current saving modes can be activated, in which the system clock of the microprocessor is reduced. The I/O modules generally use a different system clock, with the result that they can operate independently of the processing device or can be brought into a dedicated current-saving mode.

In a relatively simple control device, such as can be used, for example, on board a motor vehicle for controlling a window winder, a windshield wiper or a seat adjustment mechanism, generally the processing device and the I/O modules are operated with the same system clock, i.e. are in the same clock domain. In this case, it is essential that the I/O modules operate in fault-free fashion in order to avoid faulty operation, which can have an effect on a user. It is therefore conventional in this sector to always operate the I/O modules with the same system clock and consequently also to operate the processing device with the same system clock irrespective of its capacity utilization.

In particular a control device which is used relatively seldom, such as one for a wiper controller, wastes a considerable proportion of its potential computation power in waste heat in this way, however. This is generally undesirable and can be problematic in particular in connection with an electrically driven motor vehicle. Therefore, it is the object of the invention to provide a technology for a control device on board a motor vehicle which makes it possible to save energy when the control device is being used little or is not being used at all.

### SUMMARY OF THE INVENTION

A control device comprising a processing device, an I/O module and a clock generator for providing a system clock, wherein the processing device and the I/O module are designed to operate with the system clock of the clock generator, comprises the steps of determining that capacity utilization of the processing device is exceeding a predetermined threshold, of determining that the I/O module is in a state in which a change in the system clock is uncritical, and of changing the system clock in order to match the performance capacity of the processing device to the capacity utilization.

By virtue of taking into consideration the state of the I/O module prior to the matching, it is possible, in particular in a simple control device whose processing device uses the same system clock as the I/O module, to effect a load-dependent reduction in the system clock without running the risk of the operation of the I/O module thereby being impaired. For example in a context in which the I/O module controls a function which acts directly or indirectly on a human, the proposed procedure can advantageously be used. The invention is in particular designed for use on board a motor vehicle, in medicine technology or in industrial control systems.

In a preferred embodiment, the I/O module is designed for data transmission and it is determined that the I/O module is in a state in which a change in the system clock is uncritical if the I/O module is neither transmitting data nor receiving data directed to the control device.

It can thus be ensured that the change in the system clock does not disrupt data transmission with a remote device, wherein the remote device can control the control device or be controlled thereby. Such an uninterrupted communication capacity can be of great importance in particular when linking networks of devices on board a motor vehicle.

In a further embodiment, it is additionally determined that the processing device is in a state in which a change in the system clock is uncritical before the system clock is changed.

The processing device can tolerate a change in the system clock in particular when a program which is running on said processing device is in a corresponding state. This state can be characterized by the fact that no time-critical processing is taking place.

This procedure can also be extended to several programs or subprograms which are independent of one another and which are running cyclically, for example, on the processing device. For this purpose, the control device can comprise a counter, which is designed to count an entry and an emergence of a program implemented by the processing device into and from a critical segment with different mathematical signs. In this case, it is determined that the processing device is in a state in which a change in the system clock is uncritical if the counter has a predetermined counter reading.

As a result, a large number of conditions for enabling the change in the system clock can be combined logically with one another, with the result that the change only takes place when it is not expected that any of the components of the control device will have an impairment to their operation. The counter can be converted physically such that a concurrent change in the counter reading by a plurality of components is ruled out.

The processing device can be designed to implement a large number of programs cyclically in succession, wherein several of the programs are designed in each case to increment or decrement the counter reading on entry into or emergence from a critical segment. As a result, the freedom from faults of several programs can be assisted in a simple manner by means of the counter.

The control device can comprise a large number of I/O modules, which are designed to operate with the system clock, wherein it is determined that all of the I/O modules are in states in which a change in the system clock is uncritical before the system clock is changed. Thus, in particular I/O modules with different tasks can be switched over to a changed system clock in a fault-free manner.

In one embodiment, the system clock is reduced if the capacity utilization of the processing device is below a first threshold and is increased again once a predetermined time has elapsed. This makes it possible to ensure that predetermined tasks of the control device are implemented cyclically with a sufficiently high system clock.

In a further embodiment, the system clock is reduced if the capacity utilization is below a first threshold and is increased if the capacity utilization is above a second threshold, wherein the second threshold is higher than the first threshold. As a result, hysteresis can be provided for the change in the system clock, which hysteresis prevents an excessively frequent change in the system clock from being implemented. Phases in which the control device is used only little or not at all can thus be distinguished more effectively from phases in which the control device is used to a greater extent. In the case of a sudden change in the capacity utilization of the processing device, the system clock can also be changed by a program running on the processing device. If it has been determined, for example, that relatively complex processing is imminent or has been requested, for example because the control device has been addressed by an external device, the increase in the system clock can be triggered. In this case, there is preferably a delay until the I/O module and possibly programs which are running on the processing device are in states in which a change in the system clock is uncritical.

A computer program product according to the invention comprises program code means for implementing the described method if the computer program product is running on a processing device or is stored on a computer-readable data carrier.

A control device according to the invention comprises a clock generator for providing a system clock, a processing device, and an I/O module, wherein the processing device and the I/O module are designed to operate at the system clock of the clock generator. In this case, the processing device is designed to determine that capacity utilization of the processing device is exceeding a predetermined threshold, that the I/O module is in a state in which a change in the system clock is uncritical, and to change the system clock in order to match the performance capacity of the processing device to the capacity utilization.

The processing device can in particular be designed for implementing the above-described method. In this way, a control device can be provided which has a simple design, has a high degree of operational safety and nevertheless draws a reduced amount of current.

The I/O module can in particular be designed to implement asynchronous data transmission with an external module on the basis of the system clock. The communication capacity of the I/O module can be unimpaired despite the change in the system clock.

### BRIEF DESCRIPTION OF THE DRAWINGS

The invention will be described in more detail with reference to the attached figures, in which:

FIG. 1 shows a block circuit diagram of a control device;

FIG. 2 shows a flowchart of a method; and

FIG. 3 shows counter readings in the control device shown in FIG. 1.

### DETAILED DESCRIPTION

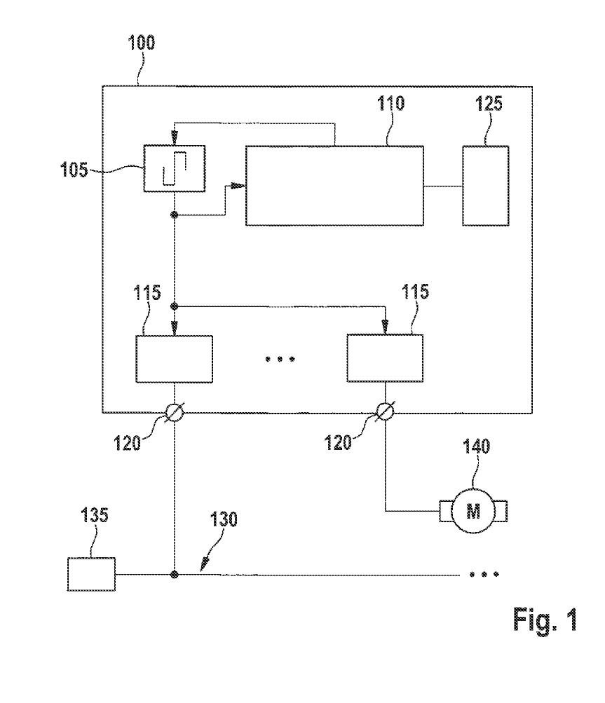

FIG. 1 shows a control device 100, in particular for use on board a motor vehicle. The control device 100 comprises a clock generator 105 for providing a system clock, a processing device 110, which can in particular be implemented as a programmable microcomputer, and one or more I/O modules 115. Each I/O module 115 can be connected to an interface 120, which can be connected to a further device outside the control device 100. In addition, the control device 100 can optionally comprise a counter 125.

In a preferred embodiment, the control device 100 is in the form of an ASIC (application-specific integrated circuit). For this, fundamental functional elements of the ASIC, for example logic gates, are interconnected such that they form the elements shown in FIG. 1. Owing to this approach, there is generally a tight coupling between the illustrated elements of the control device 100, which is reflected, for example, in the use of the same system clock for the processing device 110 and the I/O modules 115.

In the exemplary embodiment illustrated, one of the I/O modules 115 is designed to implement asynchronous data transmission on the basis of the system clock. For this purpose, the interface 120 associated with said I/O module is connected to a bus 130, which can in particular be a CAN bus or an LIN bus. One or more components 135 can be connected to the bus 130, said components being capable of implementing asynchronous data transmission with the control device 100 by means of the bus 130. The I/O module 115 can be designed to receive control signals from the bus 130 or output signals to the bus 130. In a preferred embodiment, the data transmission is performed on the bus 130 by means of a protocol which enables addressing of components 100, 140. A message which is output by the components 135 to the bus 130, for example, can be addressed to a different component 135 than the control device 100, with the result that the message can be rejected by the I/O module 115 as soon as the addressing information has been received and it has been determined that the message is irrelevant for the control device 100.

A further I/O module 115, which is illustrated on the right-hand side in FIG. 1, can be connected to another device, for example to a motor 140, by means of the interface 120 associated with said further I/O module. The motor 140 can be designed, for example, for driving a wiper arm of a wiper assembly on board the motor vehicle. In other embodiments, the motor can also be designed, for example, for operating a sliding roof or a seat adjustment mechanism.

The control device 100 is preferably used for controlling processes which do not occur very often. A large proportion of its operating time can be spent by the control device 100 waiting for a control message via the bus 130, whereas only a small proportion of its operating time is used for the subsequent control of a peripheral element, for example the motor 140. During the wait phases, there is only a low level of capacity utilization of the processing device 110, and during the active phases, there is a high capacity utilization. The capacity utilization is dimensioned according to how much time in a predetermined interval the processing device 110 spends on the implementation of a program and how much time it spends waiting for an event or a time signal. The longer the relative wait time, the lower the capacity utilization of the processing device 110 is.

The processing device 110 is designed to determine whether its capacity utilization is below a predetermined threshold value and to reduce the system clock of the clock generator 105 in this case in such a way that no components of the control device 100 are impaired by the change operation. In a corresponding manner, an increase in the system clock can also take place when the capacity utilization exceeds a predetermined threshold value.

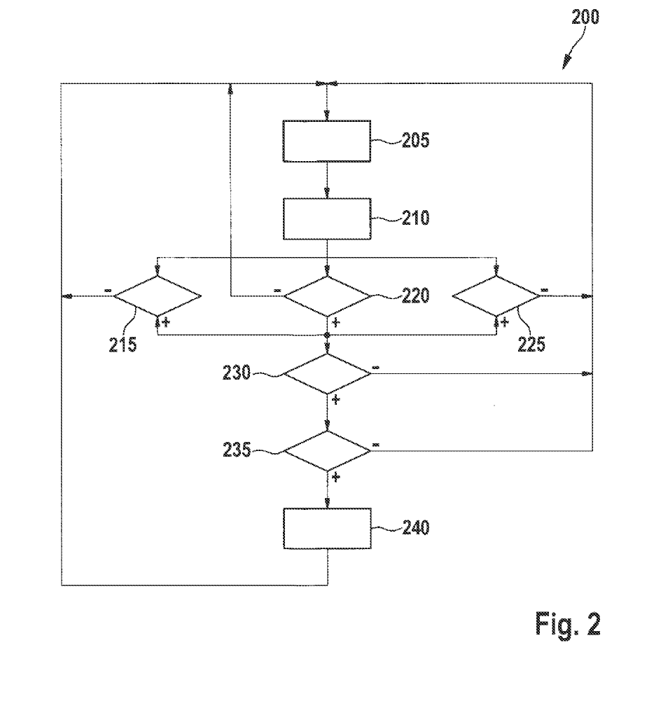

FIG. 2 shows a flowchart of a method for the control device 100, in particular for the process on the processing device 110. The method 200 begins in a step 205, in which conventional processing operation of the processing device 110 takes place. In this case, one or more programs or subprograms can be implemented for example cyclically on the processing device 110. Typically, the control device 100 does not have or has only a limited operating system, with the result that all of the programs or subprograms are implemented in accordance with the time slicing system (“round robin”) in an endless primary loop. In this case, synchronization of each individual pass generally takes place with a fixed interval time.

In a step 210, capacity utilization of the processing device 110 is determined. For this, it is possible to determine, for example, which portion of a pass through the primary loop is spent waiting for the occurrence of a condition instead of implementing a program or subprogram.

In a step 215, it is possible to check whether the capacity utilization is exceeding an upper threshold value. As an alternative to this, in a step 220, it is also possible to determine whether the capacity utilization is below a lower threshold value. In a further embodiment, the two threshold values can be identical to one another. In one variant of the method 200, steps 215 and 220 can also be implemented successively in any desired sequence. In addition, in an alternative step 225, it is possible to determine whether the system clock is low and a predetermined time has elapsed since the system clock was reduced.

If one of the tests in steps 215, 220 or 225 is positive, it is possible to determine in a step 230 whether one or more present I/O modules 115 are in a state in which a change in the system clock is uncritical. The I/O module 115 illustrated on the left-hand side in FIG. 1, which is designed for asynchronous data transmission via the bus 130, can then be in an uncritical state, for example, if no messages at all are transmitted on the bus 130. In addition, the state can also be determined as being uncritical when the I/O module 115 is not outputting any messages and messages which are transmitted on the bus 130 are not addressed to the control device 100.

The I/O module 115 illustrated on the right-hand side in FIG. 1 can be in an uncritical state if the motor 140 is not being driven. If only one of the investigated I/O modules 115 is in a state in which a change in the system clock is critical, the method 200 branches back to step 205 without a change in the system clock and can go through another pass.

Otherwise, in a step 235, it is possible to perform a check to ascertain whether the processing device 110 is in a state in which a change in the system clock is uncritical. For example, any program or subprogram running on the processing device 110 can influence a global variable which indicates whether at least one of the programs or subprograms is in a critical state in which a change in the system clock is to be avoided.

If the state of the processing device 110 has likewise been found to be uncritical in step 235, the processing device 110 instructs the clock generator 105 in a step 240 to change the system clock correspondingly. If the change takes place because the capacity utilization in step 220 has been found to be below a threshold value, the system clock is reduced, whereas if it has been found in step 215 that the capacity utilization is exceeding an upper threshold value, the system clock is increased. If it was determined in step 225 that the system clock is low and a predetermined time has elapsed since the reduction in the system clock, the system clock is likewise increased in step 240.

Following step 240, the method 200 returns to step 205 and can perform a new pass.

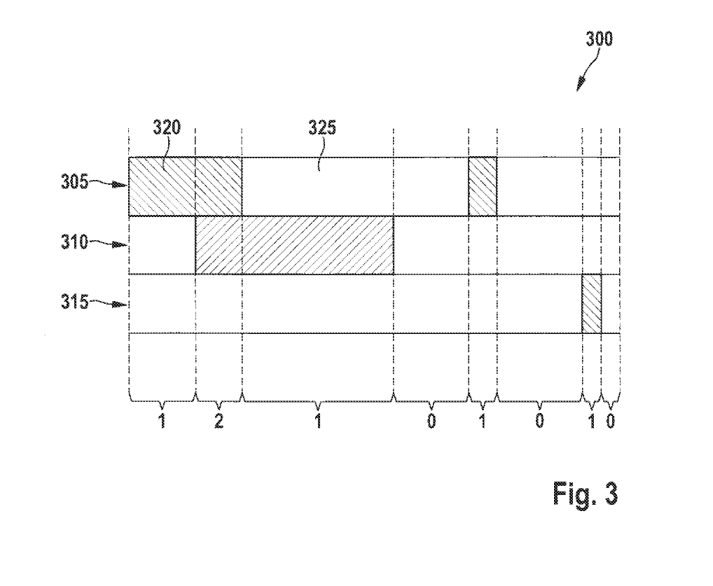

FIG. 3 shows exemplary counter readings of the counter 125 in the control device 100 shown in FIG. 1. The counter 125 can be used to implement a global variable which indicates whether a program or subprogram which is being implemented on the processing device 110 is in a critical segment. Such a global variable is also referred to as a semaphore. The counter 125 is designed to be changed at any point in time only by a single program or subprogram. Such a condition is also referred to as mutex (mutually exclusive).

A time sequence of states of a first program 305, a second program 310 and a third program 315 is illustrated in the horizontal direction. A dark area in this case corresponds in each case to a critical segment 320 and a light area corresponds to an uncritical segment 325. In each case on entry into a critical segment 320, each program 305 to 315 increases the counter reading of the counter 125 and reduces it as it exits the critical segment 320. Right at the bottom in FIG. 3, the corresponding counter readings of the counter 125 for the illustrated sequence of critical segments 320 and uncritical segments 325 of the three programs 305 to 315 are illustrated. The state of the processing device 110 is now only classified as being uncritical with respect to a change in the system clock when the counter reading of the counter 125 is zero, wherein a different predetermined counter reading can also indicate the same state. By virtue of the described procedure, it is possible to prevent a change in the system clock being implemented, while one of the programs 305 to 315 is in a critical segment 320.

1. A method (200) for a control device (100) comprising a processing device (110), an I/O module (115) and a clock generator (105), wherein the processing device (110) and the I/O module (115) are designed to operate with a system clock of the clock generator (105), said method comprising:
determining (215, 220) that capacity utilization of the processing device (110) is exceeding a predetermined threshold,
determining (230) that the I/O module (115) is in a state in which a change in the system clock is uncritical, and
changing (240) the system clock in order to match performance capacity of the processing device (110) to capacity utilization.

2. The method (200) according to claim 1, wherein the I/O module (115) is designed for data transmission and it is determined that the I/O module (115) is in a state in which a change in the system clock is uncritical if the I/O module (115) is not transmitting any data and is not receiving any data directed to the control device (100).

3. The method (200) according to claim 2, wherein it is additionally determined that the processing device (110) is in a state in which a change in the system clock is uncritical before the system clock is changed.

4. The method (200) according to claim 3, wherein the control device (100) comprises a counter, which is designed to count an entry and an emergence of a program implemented by the processing device (110) into and from a critical segment (320) with different mathematical signs, and wherein it is determined that the processing device (110) is in a state in which a change in the system clock is uncritical if the counter has a predetermined counter reading.

5. The method (200) according to claim 3, wherein the processing device (110) is designed to implement a large number of programs (305-315) cyclically in succession, and several of the programs (305-315) are designed to increment or decrement the counter reading on entry into or emergence from a critical segment (320).

6. The method (200) according to claim 1, wherein a large number of I/O modules (115) are included which are designed to operate with the system clock, and it is determined that all of the I/O modules (115) are in states in which a change in the system clock is uncritical before the system clock is changed.

7. The method (200) according to claim 1, wherein the system clock is reduced if the capacity utilization is below a first threshold and is increased once a predetermined time has elapsed.

8. The method (200) according to claim 1, wherein the system clock is reduced if the capacity utilization is below a first threshold (220) and is increased if the capacity utilization is above a second threshold (215), and wherein the second threshold is higher than the first threshold.

9. A computer program product comprising program code means for implementing the method (200) according to claim 1 when the computer program product is running on a processing device (110) or is stored on a computer-readable data carrier.

10. A control device (100), comprising:
a clock generator (105) for providing a system clock,
a processing device (110), and
an I/O module (115),
wherein the processing device (110) and the I/O module (115) are designed to operate with the system clock of the clock generator (105),
wherein the processing device (110)
a. determines that capacity utilization of the processing device (110) is exceeding a predetermined threshold,
b. such that the I/O module (115) is in a state in which a change in the system clock is uncritical, and
c. changes the system clock in order to match the performance capacity of the processing device (110) to the capacity utilization.

11. The control device (100) according to claim 10, wherein the I/O module (115) implements asynchronous data transmission with an external module (135) on the basis of the system clock.
